(19) United States
(12) Patent Application Publication
(10) Pub. No.: US 2025/0192018 A1
(43) Pub. Date: Jun. 12, 2025

(54) SEMICONDUCTOR PACKAGE INCLUDING INTERPOSER AND METHOD FOR MANUFACTURING THE SAME

(71) Applicant: Samsung Electronics Co., Ltd., Suwon-si (KR)

(72) Inventors: Byung Ho KIM, Suwon-si (KR); Youngchan KO, Suwon-si (KR); Wooseok PARK, Suwon-si (KR); Yongkoon LEE, Suwon-si (KR); MyungDo CHO, Suwon-si (KR); Hyeokjin CHU, Suwon-si (KR)

(73) Assignee: Samsung Electronics Co., Ltd., Suwon-si (KR)

(21) Appl. No.: 18/772,814

(22) Filed: Jul. 15, 2024

(30) Foreign Application Priority Data
Dec. 8, 2023 (KR) 10-2023-0177961

(51) Int. Cl. H01L 23/498; H01L 21/56; H01L 23/00; H01L 23/29; H01L 23/48; H01L 23/528; H01L 25/18; H10B 80/00

(52) U.S. Cl. CPC H01L 23/49833; H01L 21/563; H01L 23/29; H01L 23/481; H01L 23/5283; H01L 24/16; H01L 24/32; H01L 24/73; H01L 25/18; H01L 2224/16148; H01L 2224/16225; H01L 2224/32225; H01L 2224/73253; H01L 2924/1431; H01L 2924/1436; H01L 2924/19041; H10B 80/00

(57) ABSTRACT

An interposer including a first redistribution structure; a device stack structure on the first redistribution structure, the device stack structure including a first device die and a second device die on the first device die, and each of the first device die and the second device die including one or more integrated stack capacitor structures; a plurality of first connection members on the first redistribution structure; a molding material on the first redistribution structure, the molding material covering the device stack structure and the plurality of first connection members; and a second redistribution structure on the molding material.

### CROSS-REFERENCE TO RELATED APPLICATION

This application claims priority to and the benefit of Korean Patent Application No. 10-2023-0177961 filed in the Korean Intellectual Property Office on Dec. 8, 2023, the entire contents of which are incorporated herein by reference.

### BACKGROUND

The present disclosure relates to semiconductor packages including an interposer and a method for manufacturing the same.

Power integrity (PI) characteristics are important for semiconductor packages, and in order to improve power integrity (PI), it is required to implement high-capacitance capacitors. In response to this requirement, integrated stack capacitor (ISC) chips have been developed that can suppress power noise in the high frequency band of hundreds of MHz and have much higher capacitance densities than multilayer ceramic capacitors (MLCCs) and land side capacitors (LSCs).

As artificial intelligence (AI) technology advances, there is a growing demand for semiconductor packages that include logic dies and high bandwidth memories (HBMs) having high-performance circuits with faster digital signals. Semiconductor packages including high-performance circuits as mentioned above require much higher capacitance than capacitance previously required. However, since conventional integrated stack capacitor (ISC) chips have insufficient capacitance as compared to capacitance required for semiconductor packages including high-performance circuits, it is difficult to use the conventional integrated stack capacitor (ISC) chips to improve the power integrity (PI) of semiconductor packages including high-performance circuits.

Therefore, it is required to develop a new semiconductor package technology capable of improving the power integrity (PI) of a semiconductor package including a high-performance circuit.

### SUMMARY

The present disclosure is directed to an interposer that electrically couples a printed circuit board and semiconductor dies. The interposer may include a device stack structure, and the device stack structure may include a first device die, and a second device die on the first device die. Each of the first device die and the second device die may include one or more integrated stack capacitor (ISC) structures.

Embodiments of the inventive concepts provide an interposer that includes a first redistribution structure; a device stack structure on the first redistribution structure, the device stack structure including a first device die and a second device die on the first device die, and each of the first device die and the second device die including one or more integrated stack capacitor (ISC) structures; a plurality of first connection members on the first redistribution structure; a molding material on the first redistribution structure, the molding material covering the device stack structure and the plurality of first connection members; and a second redistribution structure on the molding material.

Embodiments of the inventive concepts further provide a semiconductor package that includes a printed circuit board; a first redistribution structure on the printed circuit board; a device stack structure on the first redistribution structure, the device stack structure including a first device die and a second device die on the first device die, and each of the first device die and the second device die including one or more integrated stack capacitor (ISC) structures; a plurality of connection members on the first redistribution structure; a molding material on the first redistribution structure, the molding material covering the device stack structure and the plurality of connection members; a second redistribution structure on the molding material; a first semiconductor die on the second redistribution structure; and a second semiconductor die on the second redistribution structure, the second semiconductor die being next to the first semiconductor die.

Embodiments of the inventive concepts still further provide a method of manufacturing an interposer that includes forming a first redistribution structure on a carrier; forming a plurality of connection members on the first redistribution structure; forming a device stack structure on the first redistribution structure, the device stack structure including a first device die and a second device die on the first device die, and each of the first device die and the second device die including one or more integrated stack capacitor (ISC) structures; covering the plurality of connection members and the device stack structure on the first redistribution structure with a molding material; planarizing the molding material and the plurality of connection members; and forming a second redistribution structure on the molding material.

In an interposer that electrically couples a printed circuit board and semiconductor dies, the interposer may include a device stack structure, and the device stack structure may include a first device die, and a second device die on the first device die, and each of the first device die and the second device die may include one or more integrated stack capacitor (ISC) structures.

Accordingly, it is possible to increase the number of integrated stack capacitor (ISCs) dies that are mounted in the same area of an interposer, thereby improving the power integrity (PI) of a semiconductor package.

Also, it is possible to adjust the number of integrated stack capacitor (ISC) dies that are covered by a molding material inside an interposer, thereby restraining warpage of a semiconductor package from being caused by a difference in coefficient of thermal expansion (CTE) between an integrated stack capacitor (ISC) die and the molding material in the interposer.

### BRIEF DESCRIPTION OF THE DRAWINGS

FIG. 1 is a cross-sectional view illustrating an interposer according to some example embodiments.

FIG. 2 is an enlarged cross-sectional view of a device stack structure in region A of the interposer of FIG. 1.

FIG. 3 is a cross-sectional view illustrating a semiconductor package including the interposer of FIG. 1.

FIG. 4 is a cross-sectional view illustrating an interposer according to some example embodiments.

FIG. 5 is an enlarged cross-sectional view of a device stack structure in region A of the interposer of FIG. 4.

FIG. 6 is a cross-sectional view illustrating an interposer according to some example embodiments.

FIG. 7 is an enlarged cross-sectional view of a device stack structure in region A of the interposer of FIG. 6.

FIG. 8 is a cross-sectional view illustrating an interposer according to some example embodiments.

FIG. 9 is an enlarged cross-sectional view of a device stack structure in region A of the interposer of FIG. 8.

FIGS. 10, 11, 12, 13, 14, 15, 16 and 17 are cross-sectional views for explaining a method for manufacturing an interposer of FIG. 1 according to some example embodiments.

FIGS. 18, 19, 20, 21, 22 and 23 are cross-sectional views for explaining a method for manufacturing a semiconductor package of FIG. 3 according to some example embodiments.

### DETAILED DESCRIPTION

In the following detailed description, some example embodiments of the present disclosure have been shown and described, simply by way of illustration. As those skilled in the art would realize, the described example embodiments may be modified in various different ways, all without departing from the spirit or scope of the inventive concepts.

The drawings and description are to be regarded as illustrative in nature and not restrictive. Like reference numerals designate like elements throughout the specification.

The size and thickness of each configuration shown in the drawings are arbitrarily shown for understanding and ease of description, but the inventive concepts are not limited thereto.

Throughout this specification, when a part is referred to as being “connected” to another part, it may be directly connected to the other part, or may be connected to the other part indirectly with any other elements interposed therebetween. Unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “above” or “on” a reference portion, the element is located above or below the reference portion, and it does not necessarily mean that the element is located “above” or “on” in a direction opposite to gravity.

Further, in the entire specification, when it is referred to as “on a plane” or “in plan view”, it means when a target part is viewed from above, and when it is referred to as “on a cross-section” or “in cross-sectional view”, it means when the cross-section obtained by cutting a target part vertically is viewed from the side.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, a semiconductor package 200 including an interposer 100 of some example embodiments, and a method for manufacturing the same will be described with reference to the drawings.

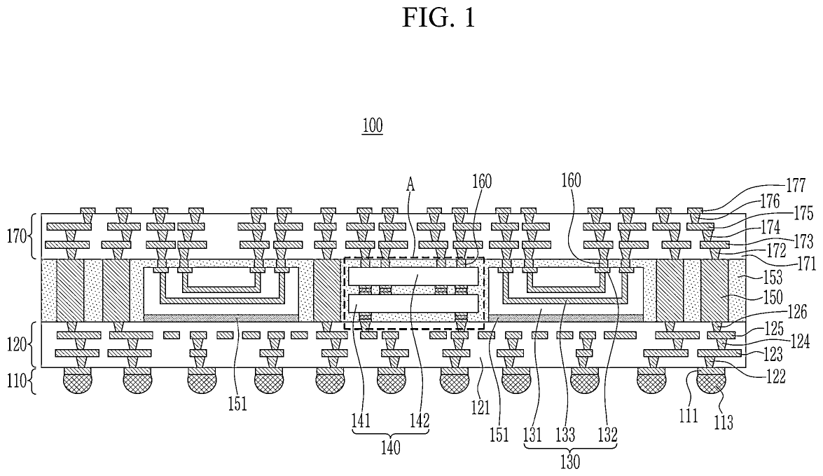

FIG. 1 is a cross-sectional view illustrating the interposer 100 of some example embodiments.

Referring to FIG. 1, the interposer 100 includes an external connection structure 110, a first redistribution structure 120, one or more bridge dies 130, a device stack structure 140, first connection members 150, second connection members 160, a first molding material 153, and a second redistribution structure 170. In some example embodiments, the interposer 100 may include a composite interposer including a redistribution structure and a molded interposer coupled to each other. In some example embodiments, the interposer 100 may be manufactured based on a fan-out wafer-level packaging (FOWLP) or fan-out panel-level packaging (FOPLP) technology.

The external connection structure 110 is disposed on the lower surface of the first redistribution structure 120. The external connection structure 110 includes conductive pads 111 and external connection members 113. Each of the conductive pads 111 is disposed between a first redistribution via 122 of the first redistribution structure 120 and an external connection member 113. Each of the conductive pads 111 electrically couples the first redistribution via 122 of the first redistribution structure 120 to the external connection member 113. The external connection members 113 electrically couple the interposer 100 to an external device (not shown in the drawings).

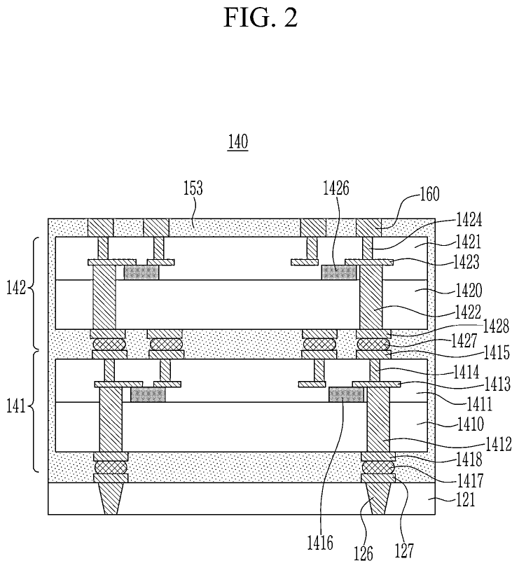

The first redistribution structure 120 includes a first dielectric 121, and the first redistribution vias 122, first redistribution lines 123, second redistribution vias 124, second redistribution lines 125, and third redistribution vias 126 in the first dielectric 121, and first bonding pads 127 (e.g., see FIG. 2) on the first dielectric 121. In some example embodiments, the first redistribution structure 120 may include less or more redistribution lines, redistribution vias, and bonding pads, which are also included in the scope of the inventive concepts.

The first dielectric 121 protects and insulates the first redistribution vias 122, the first redistribution lines 123, the second redistribution vias 124, the second redistribution lines 125, and the third redistribution vias 126. On the upper surface of the first dielectric 121, one or more bridge dies 130, the device stack structure 140, the first connection members 150, and the first molding material 153 are disposed. On the lower surface of the first dielectric 121, the external connection structure 110 is disposed.

Each of the first redistribution vias 122 is disposed between a first redistribution line 123 and a conductive pad 111. Each of the first redistribution vias 122 electrically couples a first redistribution line 123 to an external connection member 113 coupled to a conductive pad 111 in a vertical direction. Each of the first redistribution lines 123 is disposed between a first redistribution via 122 and a second redistribution via 124. Each of the first redistribution lines 123 electrically couples a first redistribution via 122 and a second redistribution via 124 in a horizontal direction. Each of the second redistribution vias 124 is disposed between a first redistribution line 123 and a second redistribution line 125. Each of the second redistribution vias 124 electrically couples a second redistribution line 125 to a first redistribution line 123 in a vertical direction. Each of the second redistribution lines 125 is disposed between a second redistribution via 124 and a third redistribution via 126. Each of the second redistribution lines 125 electrically couples a second redistribution via 124 and a third redistribution via 126 in a horizontal direction. Each of the third redistribution vias 126 is disposed between a first bonding pad 127 and a second redistribution line 125, or between a first connection member 150 and a second redistribution line 125. Each of the third redistribution vias 126 electrically couples a first bonding pad 127 to a second redistribution line 125 or electrically couples a first connection member 150 to a second redistribution line 125, in a vertical direction. Each of the first bonding pads 127 is disposed between a third redistribution via 126 and a connection member (see the reference symbol “1417” in FIG. 2) of a first device die 141 of the device stack structure 140. Each of the first bonding pads 127 electrically couples a connection member 1417 of the first device die 141 of the device stack structure 140 to a third redistribution via 126 in the vertical direction.

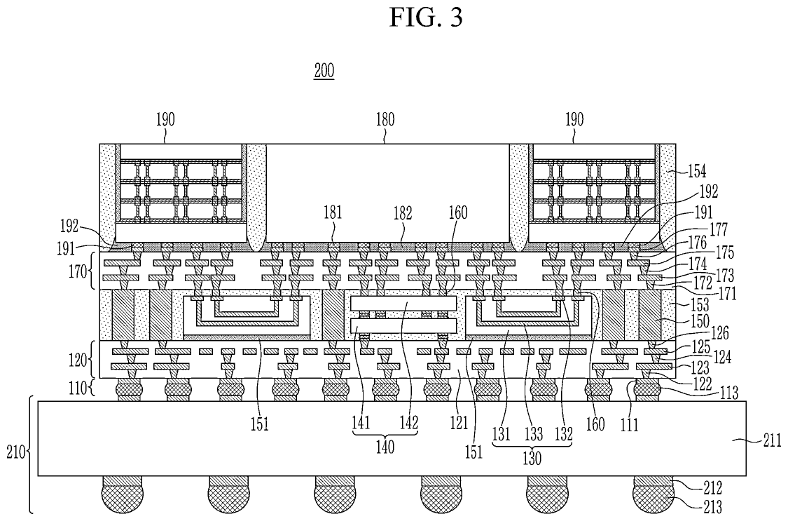

One or more bridge dies 130 are disposed between the first redistribution structure 120 and the second redistribution structure 170. The bridge dies 130 electrically couple a first semiconductor die (see the reference symbol “180” in FIG. 3) and a second semiconductor die (see the reference symbol “190” in FIG. 3) which are disposed on the second redistribution structure 170. The bridge dies 130 are attached to the first redistribution structure 120 by adhesive members 151. In some example embodiments, the adhesive members 151 may be die attach films (DAFs).

Each bridge die 130 includes a die base 131, and connection pads 132 and wiring lines 133 in the die base 131. In some example embodiments, the bridge dies 130 may include silicon bridges. The wiring lines 133 included in the die base 131 transfer data quickly in a horizontal direction. Therefore, the bridge dies 130 have a function of optimizing the signal transfer path between a first semiconductor die 180 and a second semiconductor die 190 disposed on the second redistribution structure 170 coupled to the bridge dies 130 to reduce power consumption, thereby improving the performance of the semiconductor package.

The device stack structure 140 is disposed between the first redistribution structure 120 and the second redistribution structure 170. The device stack structure 140 includes the first device die 141, and a second device die 142 on the first device die 141. Each of the first device die 141 and the second device die 142 includes one or more integrated stack capacitor (ISC) structures (see the reference symbol “1416” in FIG. 2).

The first device die 141 and the second device die 142 including the integrated stack capacitor (ISC) structures 1416 can suppress power noise in high frequency band of hundreds of MHz and have much higher capacitance densities than multilayer ceramic capacitors (MLCCs) or land side capacitors (LSCs). By forming the first device die 141 and the second device die 142 including the integrated stack capacitor (ISC) structures as a stack structure, it is possible to increase the capacitance in a semiconductor package and improve the power integrity (PI) of the semiconductor package.

The first connection members 150 are disposed on the upper surface of the first redistribution structure 120. Each of the first connection members 150 is disposed between a third redistribution via 126 of the first redistribution structure 120 and a fourth redistribution via 172 of the second redistribution structure 170. Each of the first connection members 150 electrically couples a fourth redistribution via 172 of the second redistribution structure 170 to a third redistribution via 126 of the first redistribution structure 120. The first connection members 150 are disposed through the first molding material 153. The side surfaces of the first connection members 150 are surrounded by the first molding material 153. In some example embodiments, the first connection members 150 may include conductive posts.

The second connection members 160 are disposed on the upper surfaces of one or more bridge dies 130 and on the upper surfaces of the device stack structure 140. Each of the second connection members 160 is disposed between a fourth redistribution via 172 of the second redistribution structure 170 and a connection pad 132 of the bridge dies 130, or between a fourth redistribution via 172 of the second redistribution structure 170 and a contact plug (see the reference symbol “1424” in FIG. 2) of the device stack structure 140. Each of the second connection members 160 electrically couples a fourth redistribution via 172 of the second redistribution structure 170 to a connection pad 132 of the bridge dies 130, or electrically couples a fourth redistribution via 172 of the second redistribution structure 170 to a contact plug 1424 of the device stack structure 140. The second connection members 160 are disposed through the first molding material 153. The side surfaces of the second connection members 160 are surrounded by the first molding material 153. In some example embodiments, the second connection members 160 may include micro bumps.

The first molding material 153 is disposed on the first redistribution structure 120 and covering one or more bridge dies 130, the device stack structure 140, and the first connection members 150. The first molding material 153 protects one or more bridge dies 130, the device stack structure 140, and the first connection members 150 from the external environment. Accordingly, it is possible to secure electrical or mechanical stability of the interposer 100.

The second redistribution structure 170 is disposed on the first connection members 150, the second connection members 160, and the first molding material 153. The second redistribution structure 170 includes a second dielectric 171; the fourth redistribution vias 172, third redistribution lines 173, fifth redistribution vias 174, fourth redistribution lines 175, and sixth redistribution vias 176 in the second dielectric 171; and second bonding pads 177 on the second dielectric 171. In some example embodiments, the second redistribution structure 170 may include less or more redistribution lines, redistribution vias, and bonding pads, which are also included in the scope of the inventive concepts.

The second dielectric 171 protects and insulates the fourth redistribution vias 172, the third redistribution lines 173, the fifth redistribution vias 174, the fourth redistribution lines 175, and the sixth redistribution vias 176. On the lower surfaces of the second dielectric 171, the first connection members 150, the second connection members 160, and the first molding material 153 are disposed.

Each of the fourth redistribution vias 172 is disposed between a first connection member 150 and a third redistribution line 173, or between a second connection member 160 and a third redistribution line 173. Each of the fourth redistribution vias 172 electrically couples a third redistribution line 173 to a first connection member 150, or electrically couples a third redistribution line 173 to a second connection member 160, in a vertical direction. Each of the third redistribution lines 173 is disposed between a fourth redistribution via 172 and a fifth redistribution via 174. Each of the third redistribution lines 173 electrically couples a fourth redistribution via 172 and a fifth redistribution via 174 in a horizontal direction. Each of the fifth redistribution vias 174 is disposed between a third redistribution line 173 and a fourth redistribution line 175. Each of the fifth redistribution vias 174 electrically couples a fourth redistribution line 175 to a third redistribution line 173 in a vertical direction. Each of the fourth redistribution lines 175 is disposed between a fifth redistribution via 174 and a sixth redistribution via 176. Each of the fourth redistribution lines 175 electrically couples a fifth redistribution via 174 and a sixth redistribution via 176 in a horizontal direction. Each of the sixth redistribution vias 176 is disposed between a fourth redistribution line 175 and a second bonding pad 177. Each of the sixth redistribution vias 176 electrically couples a second bonding pad 177 to a fourth redistribution line 175 in a vertical direction. Each of the second bonding pads 177 is disposed on a sixth redistribution via 176. Each of the second bonding pads 177 electrically couples a connection member (see the reference symbol “181” in FIG. 3) of the first semiconductor die 180 to a sixth redistribution via 176, or electrically couples a connection member (see the reference symbol “191” in FIG. 3) of the second semiconductor die 190 to a sixth redistribution via 176.

FIG. 2 is an enlarged cross-sectional view of the device stack structure 140 in region A of the interposer 100 of FIG. 1.

Referring to FIGS. 1 and 2, the device stack structure 140 includes the first device die 141 and the second device die 142. The first device die 141 is disposed on the first redistribution structure 120. The first device die 141 includes a substrate 1410, an inter-metal dielectric (IMD) 1411, through-silicon vias (TSVs) 1412, wiring lines 1413, contact plugs 1414, connection pads 1415, one or more integrated stack capacitor structures 1416, the connection members 1417, and conductive pad 1418. In some example embodiments, the first device die 141 may be a surface mount device (SMD). In some example embodiments, the first device die 141 may be an integrated stack capacitor (ISC) die.

The substrate 1410 is a die formed from a wafer. In some example embodiments, the substrate 1410 may comprise silicon or other semiconductor materials.

The inter-metal dielectric (IMD) 1411 covers and insulates some portions of the through-silicon vias (TSVs) 1412, the wiring lines 1413, the contact plugs 1414, and one or more integrated stack capacitor structures 1416. In some example embodiments, the inter-metal dielectric (IMD) 1411 may comprise silicon oxide, silicon nitride, silicon oxynitride, TEOS formed oxide, PSP, BPSG, low-k dielectric materials, other suitable dielectric materials, or combinations thereof.

The through-silicon vias (TSVs) 1412 extend from the inter-metal dielectric (IMD) 1411 so as to pass through the substrate 1410. A first end of each of the through-silicon vias (TSVs) 1412 is coupled to a wiring line 1413, and a second end of each is coupled to a conductive pad 1418. In some example embodiments, the through-silicon vias (TSVs) 1412 may comprise at least one of tungsten, aluminum, copper, and alloys thereof.

The wiring lines 1413 and the contact plugs 1414 are signal lines for transferring signals between individual devices and power lines for transferring power to individual devices.

The wiring lines 1413 are horizontally formed so as to transfer signals and power between layers which are at a level with one another. For example, each of the wiring lines 1413 is disposed between a through-silicon via (TSV) 1412 and a contact plug 1414. For example, each of the wiring lines 1413 electrically couples a contact plug 1414 to a through-silicon via (TSV) 1412.

The contact plugs 1414 are vertically formed so as to transfer signals and power between layers which are at different level layers. Each of the contact plugs 1414 is disposed between a wiring line 1413 and a connection pad 1415. Each of the contact plugs 1414 electrically couples a connection pad 1415 to a wiring line 1413.

In some example embodiments, each of the wiring lines 1413 and the contact plugs 1414 may comprise at least one of copper, aluminum, tungsten, nickel, gold, tin, titanium, and alloys thereof. In some example embodiments, the first device die 141 may include fewer or more wiring lines and contact plugs, which are also within the scope of the inventive concepts.

Each of the connection pads 1415 is disposed between a contact plug 1414 and a connection member 1427 of the second device die 142. Each of the connection pads 1415 electrically couples a connection member 1427 of the second device die 142 to a contact plug 1414. In some example embodiments, the connection pads 1415 may comprise at least one of copper, nickel, zinc, gold, silver, platinum, palladium, chromium, titanium, and alloys thereof.

One or more integrated stack capacitor (ISC) structures 1416 are coupled to the wiring lines 1413 inside the inter-metal dielectric (IMD) 1411. One or more integrated stack capacitor (ISC) structures 1416 includes capacitor structures, each of which includes a lower electrode, a dielectric film, and an upper electrode. The capacitor structures consecutively extend in the vertical direction inside a vertical cylinder structure where tens of thousands or more capacitor structures are arranged, and consecutively extend in the horizontal direction on an insulating layer where the vertical cylinder structure is formed. Therefore, one or more integrated stack capacitor (ISC) structures 1416 have a three-dimensional capacitor structure in the horizontal and vertical directions, and have higher capacitance as compared to conventional multilayer ceramic capacitors (MLCCs) or LSCs. In some example embodiments, the first device die 141 may have a vertical thickness of about 30 μm to about 50 μm.

Each of the connection members 1417 is disposed between a conductive pad 1418 and a first bonding pad 127 of the first redistribution structure 120. Each of the connection members 1417 electrically couples a conductive pad 1418 to a first bonding pad 127. Each of the conductive pads 1418 is disposed between a connection member 1417 and a through-silicon via (TSV) 1412. Each of the conductive pads 1418 electrically couples a through-silicon via (TSV) 1412 to a connection member 1417. In some example embodiments, the connection members 1417 may comprise at least one of tin, silver, lead, nickel, copper, or alloys thereof. In some example embodiments, the connection members 1417 may include micro bumps or solder balls. In some example embodiments, the conductive pads 1418 may comprise at least one of copper, nickel, zinc, gold, silver, platinum, palladium, chromium, titanium, and alloys thereof.

The second device die 142 is disposed on the first device die 141. The second device die 142 includes a substrate 1420, an inter-metal dielectric (IMD) 1421, through-silicon vias (TSVs) 1422, wiring lines 1423, contact plugs 1424, one or more integrated stack capacitor structures 1426, connection members 1427, and conductive pads 1428. In some example embodiments, the second device die 142 may be a surface mount device (SMD). In some example embodiments, the second device die 142 may be an integrated stack capacitor (ISC) die.

The second device die 142 is the uppermost structure of the device stack structure 140, and is electrically coupled to the second connection members 160. The second device die 142 is electrically coupled to the connection pads 1415 of the first device die 141 below the second device die 142 by the connection members 1427.

With respect to the substrate 1420, the inter-metal dielectric (IMD) 1421, the through-silicon vias (TSVs) 1422, the wiring lines 1423, the contact plugs 1424, one or more integrated stack capacitor structures 1426, the connection members 1427, and the conductive pads 1428 other than the above-mentioned contents, the contents about the substrate 1410, the inter-metal dielectric (IMD) 1411, the through-silicon vias (TSVs) 1412, the wiring lines 1413, the contact plugs 1414, one or more integrated stack capacitor structures 1416, the connection members 1417, and the conductive pads 1418 described with respect to the first device die 141 may be applied. In some example embodiments, the second device die 142 may have a vertical thickness of about 30 μm to about 50 μm.

As described above, according to the inventive concepts, it is possible to increase the number of integrated stack capacitor (ISC) dies that are mounted in the same area of the interposer 100, thereby increasing the capacitance in the interposer 100 and improving the power integrity (PI) of a semiconductor package.

Also, it is possible to adjust the ratio of silicon which is the main material of integrated stack capacitor (ISC) dies in the interposer 100 by adjusting the number of integrated stack capacitor (ISC) dies that are covered by the first molding material 153 inside the interposer 100, whereby it is possible to restrain warpage of the interposer 100 from being caused by a difference in coefficient of thermal expansion (CTE) between individual components.

FIG. 3 is a cross-sectional view illustrating a semiconductor package 200 including the interposer 100 of FIG. 1.

Referring to FIGS. 1 and 3, the semiconductor package 200 includes the interposer 100, the first semiconductor die 180, one or more second semiconductor dies 190, a second molding material 154, and a printed circuit board 210. In some example embodiments the semiconductor package 200 may be manufactured based on a fan-out wafer-level packaging (FOWLP) or fan-out panel-level packaging (FOPLP) technology.

The first semiconductor die 180 is disposed on the second redistribution structure 170. The first semiconductor die 180 is disposed side by side with the second semiconductor dies 190. The first semiconductor die 180 is electrically coupled to the second redistribution structure 170 by connection members 181. In some example embodiments, the first semiconductor die 180 may include a logic die. In some example embodiments, the first semiconductor die 180 may include a system-on-chip (SoC). In some example embodiments, the first semiconductor die 180 may include at least one of central processing units (CPUs) and graphic processing units (GPUs).

Each of the connection members 181 is disposed between a second bonding pad 177 and the first semiconductor die 180 so as to electrically couple the first semiconductor die 180 to the second bonding pad 177. In some example embodiments, the connection members 181 may include micro bumps or solder balls. In some example embodiments, the connection members 181 may comprise at least one of tin, silver, lead, nickel, copper, or alloys thereof.

An insulating member 182 may be positioned between the second redistribution structure 170 and the first semiconductor die 180 so as to surround and protect the connection members 181 and the second bonding pads 177. In some example embodiments, the insulating member 182 may include non-conductive film (NCF). In some example embodiments, the insulating member 182 may include a capillary underfill (CUF).

One or more second semiconductor dies 190 are disposed on the second redistribution structure 170. The second semiconductor dies 190 are disposed side by side with the first semiconductor die 180. The second semiconductor dies 190 are electrically coupled to the second redistribution structure 170 by connection members 191. In some example embodiments, the second semiconductor dies 190 may include a high bandwidth memory (HBM). The high bandwidth memory (HBM) is a high-performance three-dimensional (3D) stacked dynamic random access memory (DRAM). The high bandwidth memory (HBM) may be manufactured by vertically stacking memory dies on a buffer chip to form one memory stack by performing hybrid bonding or using micro bumps.

Each of the connection members 191 is disposed between a second bonding pad 177 and a second semiconductor die 190 so as to electrically couple the second semiconductor die 190 to the second bonding pad 177. In some example embodiments, the connection members 191 may include micro bumps or solder balls. In some example embodiments, the connection members 191 may comprise at least one of tin, silver, lead, nickel, copper, or alloys thereof.

An insulating member 192 may be positioned between the second redistribution structure 170 and the second semiconductor dies 190 so as to surround and protect the connection members 191 and the second bonding pads 177. In some example embodiments, the insulating member 192 may include non-conductive film (NCF). In some example embodiments, the insulating member 192 may include a capillary underfill (CUF).

The second molding material 154 is positioned on the second redistribution structure 170 so as to cover the first semiconductor die 180, one or more second semiconductor dies 190, and the insulating members 182 and 192. The second molding material 154 protects the first semiconductor die 180, one or more second semiconductor dies 190, and the insulating members 182 and 192 from the external environment. Accordingly, it is possible to secure the electrical or mechanical stability of the semiconductor package 200.

The printed circuit board 210 is disposed on the lower surface of the first redistribution structure 120, and is electrically coupled to the external connection structure 110. The printed circuit board 210 includes a substrate base 211, conductive pads 212, and connection members 213. The substrate base 211 is electrically coupled to an external device by the conductive pads 212 and the connection members 213. In some example embodiments, the conductive pads 212 may comprise at least one of copper, nickel, zinc, gold, silver, platinum, palladium, chromium, titanium, and alloys thereof. In some example embodiments, the connection members 213 may comprise at least one of tin, silver, lead, nickel, copper, or alloys thereof. In some example embodiments, the connection members 213 may include solder balls.

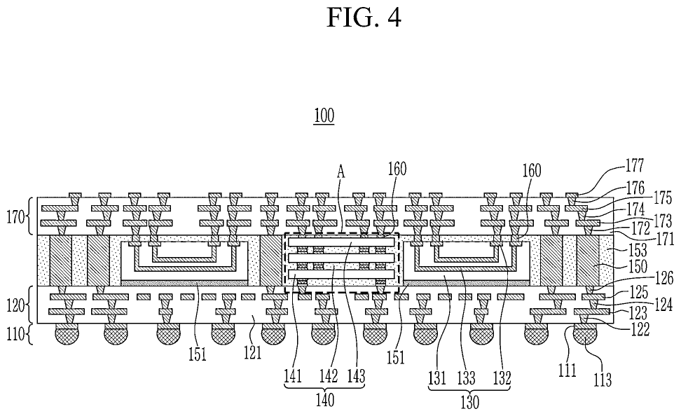

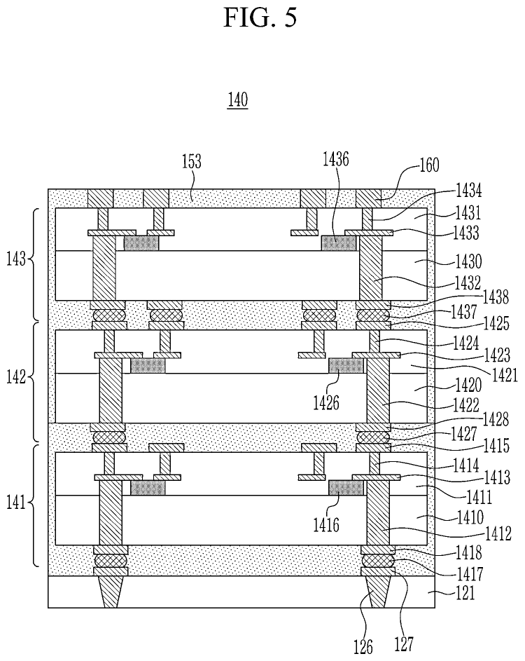

FIG. 4 is a cross-sectional view illustrating an interposer 100 of some example embodiments, and FIG. 5 is an enlarged cross-sectional view of a device stack structure 140 in region A of the interposer 100 of FIG. 4.

Referring to FIGS. 4 and 5, the interposer 100 includes a device stack structure 140. The device stack structure 140 includes a first device die 141, a second device die 142 on the first device die 141, and a third device die 143 on the second device die 142. Each of the first device die 141, the second device die 142, and the third device die 143 includes one or more integrated stack capacitor (ISC) structures.

The contents described in the contents related to FIG. 2 may be equally applied to the first device die 141.

The second device die 142 is disposed on the first device die 141. The second device die 142 includes a substrate 1420, an inter-metal dielectric (IMD) 1421, through-silicon vias (TSVs) 1422, wiring lines 1423, contact plugs 1424, connection pads 1425, one or more integrated stack capacitor structures 1426, connection members 1427, and conductive pads 1428. In some example embodiments, the second device die 142 may be a surface mount device (SMD). In some example embodiments, the second device die 142 may be an integrated stack capacitor (ISC) die.

The second device die 142 is an intermediate structure of the device stack structure 140, and is electrically coupled to the third device die 143 by connection members 1437. The second device die 142 is electrically coupled to the connection pads 1415 of the first device die 141 below the second device die 142 by the connection members 1427.

With respect to the substrate 1420, the inter-metal dielectric (IMD) 1421, the through-silicon vias (TSVs) 1422, the wiring lines 1423, the contact plugs 1424, the connection pads 1425, one or more integrated stack capacitor structures 1426, the connection members 1427, and the conductive pads 1428 other than the above-mentioned contents, the contents about the substrate 1410, the inter-metal dielectric (IMD) 1411, the through-silicon vias (TSVs) 1412, the wiring lines 1413, the contact plugs 1414, the connection pads 1415, one or more integrated stack capacitor structures 1416, the connection members 1417, and the conductive pads 1418 described with respect to the first device die 141 may be applied.

The third device die 143 is disposed on the second device die 142. The third device die 143 includes a substrate 1430, an inter-metal dielectric (IMD) 1431, through-silicon vias (TSVs) 1432, wiring lines 1433, contact plugs 1434, one or more integrated stack capacitor structures 1436, connection members 1437, and conductive pads 1438. In some example embodiments, the third device die 143 may be a surface mount device (SMD). In some example embodiments, the third device die 143 may be an integrated stack capacitor (ISC) die.

The third device die 143 is the uppermost structure of the device stack structure 140, and is electrically coupled to the second connection members 160. The third device die 143 is electrically coupled to the connection pads 1425 of the second device die 142 below the third device die 143 by the connection members 1437.

With respect to the substrate 1430, the inter-metal dielectric (IMD) 1431, the through-silicon vias (TSVs) 1432, the wiring lines 1433, the contact plugs 1434, one or more integrated stack capacitor structures 1436, the connection members 1437, and the conductive pads 1438 other than the above-mentioned contents, the contents about the substrate 1410, the inter-metal dielectric (IMD) 1411, the through-silicon vias (TSVs) 1412, the wiring lines 1413, the contact plugs 1414, one or more integrated stack capacitor structures 1416, the connection members 1417, and the conductive pads 1418 described with respect to the first device die 141 may be applied.

As described above, according to the inventive concepts, it is possible to increase the number of integrated stack capacitor (ISC) dies that are mounted in the same area of the interposer 100, thereby increasing the capacitance in the interposer 100 and improving the power integrity (PI) of a semiconductor package.

Also, it is possible to adjust the ratio of silicon which is the main material of integrated stack capacitor (ISC) dies in the interposer 100 by adjusting the number of integrated stack capacitor (ISC) dies that are covered by the first molding material 153 inside the interposer 100, whereby it is possible to restrain warpage of the interposer 100 from being caused by a difference in coefficient of thermal expansion (CTE) between individual components.

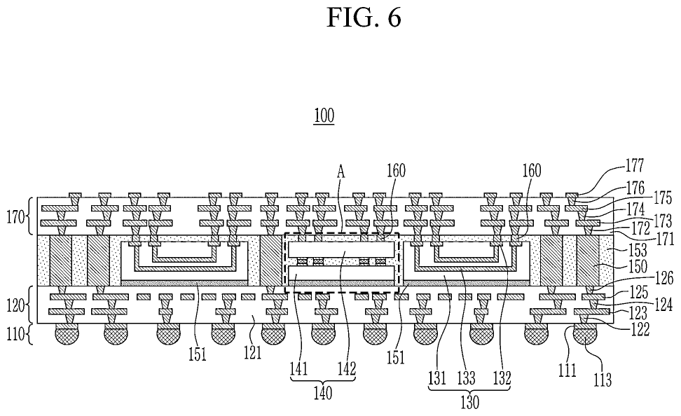

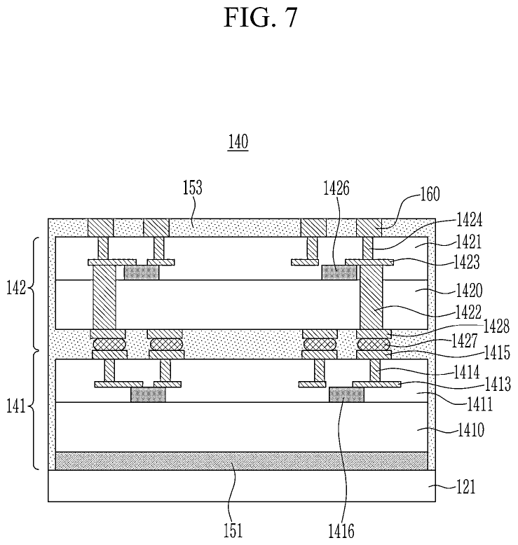

FIG. 6 is a cross-sectional view illustrating an interposer 100 of an some example embodiments, and FIG. 7 is an enlarged cross-sectional view of a device stack structure 140 in region A of the interposer 100 of FIG. 6.

Referring to FIGS. 6 and 7, the interposer 100 includes a device stack structure 140. The device stack structure 140 includes a first device die 141, and a second device die 142 on the first device die 141. The first device die 141 is attached to a first redistribution structure 120 by an adhesive member 151. In some example embodiments, the adhesive member 151 may be die attach film (DAF). The first device die 141 does not include through-silicon vias (TSVs), and connection members and conductive pads on the lower surface of a substrate 1410.

With respect to the first device die 141 and the second device die 142 other than the above-mentioned contents, the contents about the first device die 141 and the second device die 142 described with respect to FIG. 2 may be applied.

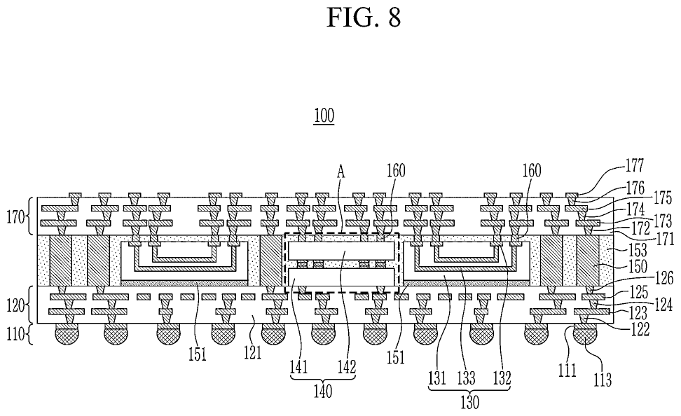

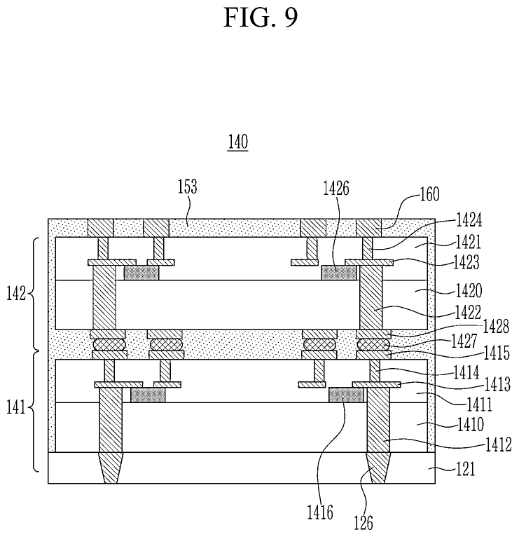

FIG. 8 is a cross-sectional view illustrating an interposer 100 of some example embodiments, and FIG. 9 is an enlarged cross-sectional view of a device stack structure 140 in region A of the interposer 100 of FIG. 8.

Referring to FIGS. 8 and 9, the interposer 100 includes a device stack structure 140. The device stack structure 140 includes a first device die 141, and a second device die 142 on the first device die 141. The first device die 141 is attached to a first redistribution structure 120 by performing a thermal compression (TC) process. Each of through-silicon vias (TSVs) 1412 of the first device die 141 is directly bonded to a third redistribution via 126 of the first redistribution structure 120. The first device die 141 does not include connection members and conductive pads on the lower surface of a substrate 1410.

With respect to the first device die 141 and the second device die 142 other than the above-mentioned contents, the contents about the first device die 141 and the second device die 142 described with respect to FIG. 2 may be applied.

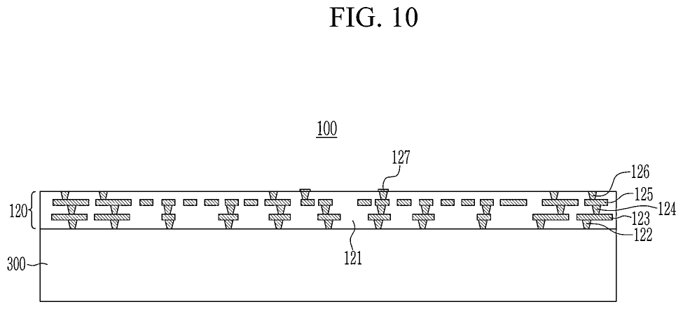

FIGS. 10 to 17 are cross-sectional views for explaining a method for manufacturing the interposer 100 of FIG. 1.

FIG. 10 is a cross-sectional view illustrating an operation of forming the first redistribution structure 120 on a carrier 300

Referring to FIG. 10, the first redistribution structure 120 is formed on the carrier 300. First, the carrier 300 is provided. In some example embodiments, the carrier 300 may comprise a silicon-based material such as glass or silicon oxide, an organic material, other materials such as aluminum oxide, any combination thereof, etc.

Next, a first dielectric 121 is formed on the carrier 300. In some example embodiments, the first dielectric 121 may comprise a photoimageable dielectric (PID) (a photosensitive dielectric) to be used in a redistribution process. The photoimageable dielectric is a material applicable to a photolithography process to form fine patterns. In some example embodiments, the photoimageable dielectric (PID) may comprise a polyimide-based photosensitive polymer, a NOVOLAC® (industrial grade epoxy) based photosensitive polymer, polybenzoxazole, a silicon-based polymer, an acrylate-based polymer, or an epoxy-based polymer. In some example embodiments, the first dielectric 121 may be formed by spin coating.

After the first dielectric 121 is formed, the first dielectric 121 is selectively etched to form via holes, and the via holes are filled with a conductive material to form the first redistribution vias 122.

Subsequently, an additional first dielectric 121 is deposited on the first redistribution vias 122 and the first dielectric 121, and the disposed additional first dielectric 121 is selectively etched to form openings, and the openings are filled with a conductive material to form the first redistribution lines 123.

Next, an additional first dielectric 121 is deposited on the first redistribution lines 123 and the first dielectric 121, and the disposed additional first dielectric 121 is selectively etched to form via holes, and the via holes are filled with a conductive material to form the second redistribution vias 124.

Subsequently, an additional first dielectric 121 is deposited on the second redistribution vias 124 and the first dielectric 121, and the disposed additional first dielectric 121 is selectively etched to form openings, and the openings are filled with a conductive material to form the second redistribution lines 125.

Next, an additional first dielectric 121 is deposited on the second redistribution lines 125 and the first dielectric 121, and the disposed additional first dielectric 121 is selectively etched to form via holes, and the via holes are filled with a conductive material to form the third redistribution vias 126.

Subsequently, the first bonding pads 127 are formed by depositing photoresist (not shown in the drawings) on the third redistribution vias 126 and the first dielectric 121, selectively exposing and developing the photoresist to form photoresist patterns including openings, and filling the openings with a conductive material.

In some example embodiments, each of the first redistribution vias 122, the first redistribution lines 123, the second redistribution vias 124, the second redistribution lines 125, the third redistribution vias 126, and the first bonding pads 127 may comprise at least one of copper, aluminum, tungsten, nickel, gold, tin, titanium, and alloys thereof. In some example embodiments, each of the first redistribution vias 122, the first redistribution lines 123, the second redistribution vias 124, the second redistribution lines 125, the third redistribution vias 126, and the first bonding pads 127 may be formed by performing a sputtering process. In some example embodiments, each of the first redistribution vias 122, the first redistribution lines 123, the second redistribution vias 124, the second redistribution lines 125, the third redistribution vias 126, and the first bonding pads 127 may be formed by forming a seed metal layer and then performing an electroplating process.

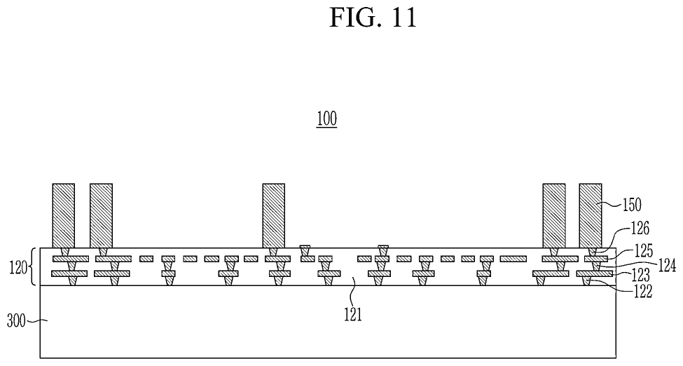

FIG. 11 is a cross-sectional view illustrating an operation of forming the first connection members 150 on the first redistribution structure 120.

Referring to FIG. 11, the first connection members 150 may be formed in the vertical direction on the first redistribution structure 120. In some example embodiments, the first connection members 150 may be formed by performing a sputtering process. In some example embodiments, the first connection members 150 may be formed by forming seed metal layers and then performing an electroplating process. In some example embodiments, the first connection members 150 may comprise at least one of copper, aluminum, tungsten, nickel, gold, silver, chromium, antimony, tin, titanium, and alloys thereof.

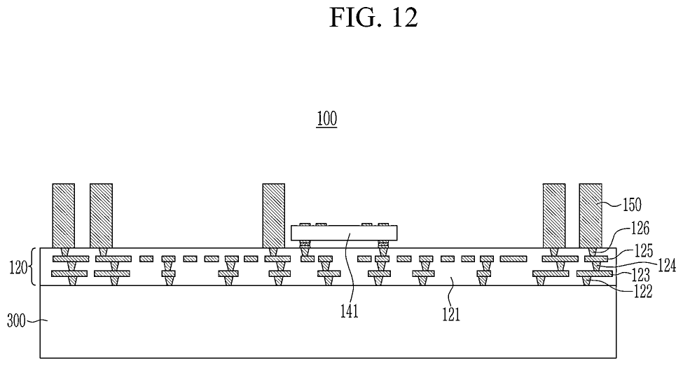

FIG. 12 is a cross-sectional view illustrating an operation of mounting the first device die 141 on the first redistribution structure 120.

Referring to FIG. 12, the first device die 141 is mounted on the first redistribution structure 120 by performing flip-chip bonding. In some example embodiments of the interposer 100 of FIG. 6, the first device die 141 is attached to the first redistribution structure 120 by the adhesive members 151. In the some example embodiments of the interposer 100 of FIG. 8, the first device die 141 is bonded to the third redistribution vias 126 of the first redistribution structure 120 by a thermal compression (TC) process.

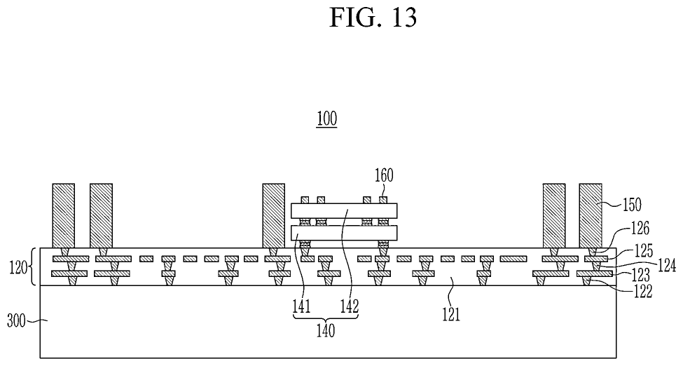

FIG. 13 is a cross-sectional view illustrating an operation of mounting the second device die 142 on the first device die 141.

Referring to FIG. 13, the second device die 142 is mounted on the first device die 141 by performing flip-chip bonding. Through this operation, the second device die 142 is electrically coupled to the first device die 141.

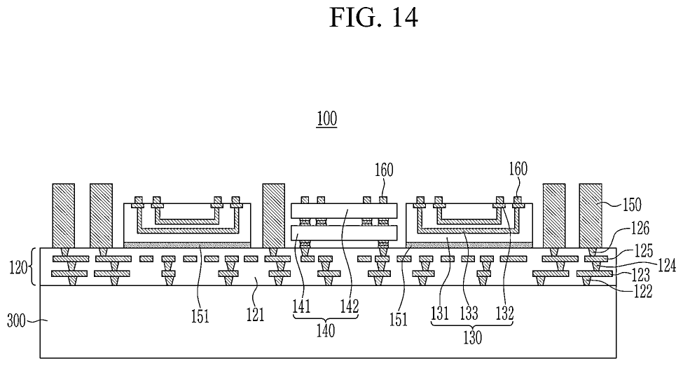

FIG. 14 is a cross-sectional view illustrating an operation of mounting one or more bridge dies 130 on the first redistribution structure 120.

Referring to FIG. 14, one or more bridge dies 130 are attached to the first redistribution structure 120 by the adhesive members 151.

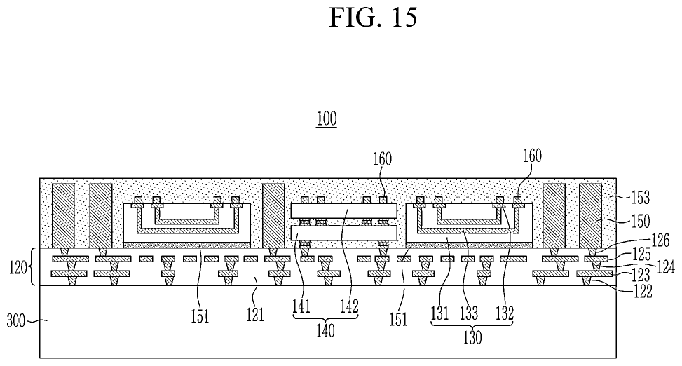

FIG. 15 is a cross-sectional view illustrating an operation of encapsulating one or more bridge dies 130, the device stack structure 140, the first connection members 150, and the second connection members 160 on the first redistribution structure 120.

Referring to FIG. 15, one or more bridge dies 130, the device stack structure 140, the first connection members 150, and the second connection members 160 are covered on the first redistribution structure 120 by the first molding material 153. In some example embodiments, the process of performing encapsulating by the first molding material 153 may include a compression molding or transfer molding process. In some example embodiments, the first molding material 153 may comprise an epoxy molding compound (EMC).

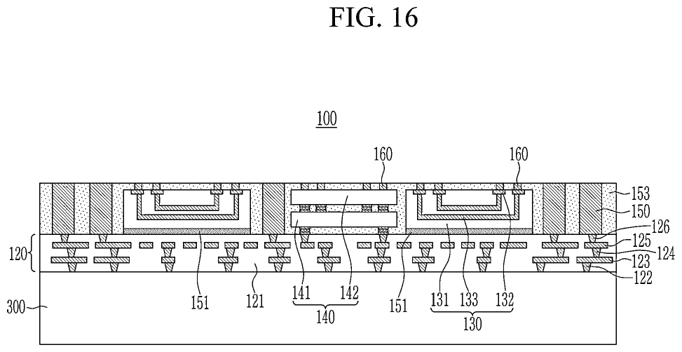

FIG. 16 is a cross-sectional view illustrating an operation of performing a chemical mechanical polishing (CMP) process on the first connection members 150 and the first molding material 153.

Referring to FIG. 16, by performing the chemical mechanical polishing (CMP) process to level the upper surfaces of the first connection members 150 and the upper surface of the first molding material 153, the upper surfaces of the first connection members 150 and the upper surface of the first molding material 153 are planarized. After the chemical mechanical polishing (CMP) process is performed, the upper surfaces of the first connection members 150 and the upper surfaces of the second connection members 160 are exposed. For example, in some example embodiments planarizing of the upper surfaces of the first connection members 150 and the upper surface of the first molding material 153 may be by grinding.

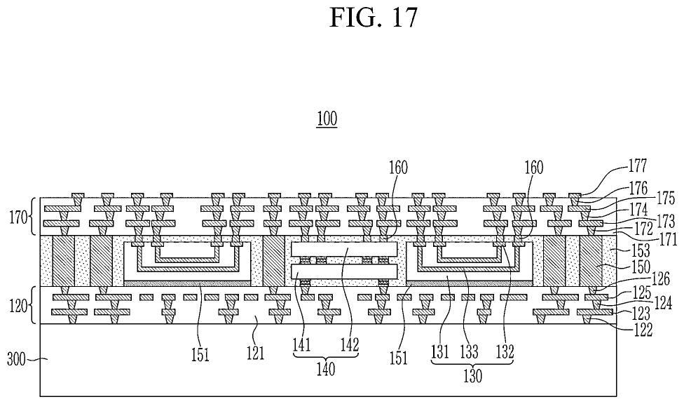

FIG. 17 is a cross-sectional view illustrating an operation of forming the second redistribution structure 170 on the first molding material 153.

Referring to FIG. 17, the second redistribution structure 170 is formed on the first connection members 150, the second connection members 160, and the first molding material 153.

First, a second dielectric 171 is formed on the first connection members 150, the second connection members 160, and the first molding material 153. In some example embodiments, the second dielectric 171 may comprise a photoimageable dielectric (PID) (a photosensitive dielectric) to be used in a redistribution process. The photoimageable dielectric is a material applicable to a photolithography process to form fine patterns. In an some example embodiments, the photoimageable dielectric (PID) may comprise a polyimide-based photosensitive polymer, a NOVOLAC® (industrial grade epoxy) based photosensitive polymer, polybenzoxazole, a silicon-based polymer, an acrylate-based polymer, or an epoxy-based polymer. In some example embodiments, the second dielectric 171 may be formed by spin coating.

After the second dielectric 171 is formed, the second dielectric 171 is selectively etched to form via holes, and the via holes are filled with a conductive material to form the fourth redistribution vias 172.

Subsequently, an additional second dielectric 171 is deposited on the fourth redistribution vias 172 and the second dielectric 171, and disposed additional second dielectric 171 is selectively etched to form openings, and the openings are filled with a conductive material to form the third redistribution lines 173.

Next, an additional second dielectric 171 is deposited on the third redistribution lines 173 and the second dielectric 171, and the disposed additional second dielectric 171 is selectively etched to form via holes, and the via holes are filled with a conductive material to form the fifth redistribution vias 174.

Subsequently, an additional second dielectric 171 is deposited on the fifth redistribution vias 174 and the second dielectric 171, and the disposed additional second dielectric 171 is selectively etched to form openings, and the openings are filled with a conductive material to form the fourth redistribution lines 175.

Next, an additional second dielectric 171 is deposited on the fourth redistribution lines 175 and the second dielectric 171, and the disposed additional second dielectric 171 is selectively etched to form via holes, and the via holes are filled with a conductive material to form the sixth redistribution vias 176.

Subsequently, the second bonding pads 177 are formed by depositing photoresist (not shown in the drawings) on the sixth redistribution vias 176 and the second dielectric 171, selectively exposing and developing the photoresist to form photoresist patterns including openings, and filling the openings with a conductive material.

In some example embodiments, each of the fourth redistribution vias 172, the third redistribution lines 173, the fifth redistribution vias 174, the fourth redistribution lines 175, the sixth redistribution vias 176, and the second bonding pads 177 may comprise at least one of copper, aluminum, tungsten, nickel, gold, tin, titanium, and alloys thereof. In some example embodiments, each of the fourth redistribution vias 172, the third redistribution lines 173, the fifth redistribution vias 174, the fourth redistribution lines 175, the sixth redistribution vias 176, and the second bonding pads 177 may be formed by performing a sputtering process. In some example embodiments, each of the fourth redistribution vias 172, the third redistribution lines 173, the fifth redistribution vias 174, the fourth redistribution lines 175, the sixth redistribution vias 176, and the second bonding pads 177 may be formed by forming a seed metal layer and then performing an electroplating process.

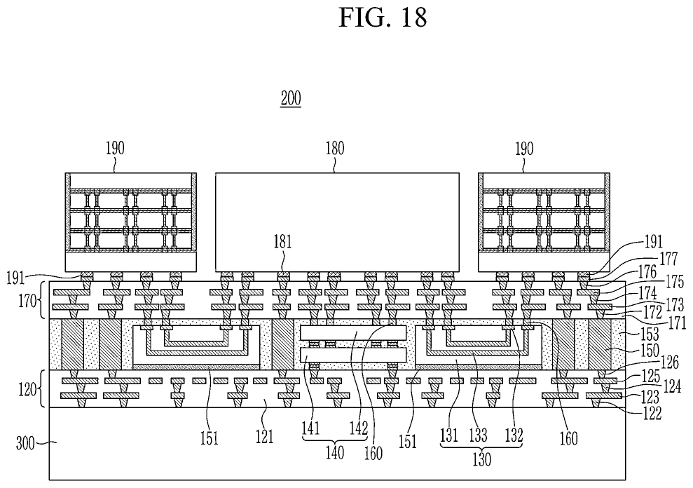

FIGS. 18 to 23 are cross-sectional views for explaining a method for manufacturing the semiconductor package 200 of FIG. 3.

FIG. 18 is a cross-sectional view illustrating an operation of mounting the first semiconductor die 180 and one or more second semiconductor dies 190 on the second redistribution structure 170.

Referring to FIG. 18, the first semiconductor die 180 and one or more second semiconductor dies 190 are mounted on the second redistribution structure 170 by performing flip chip bonding. The first semiconductor die 180 is bonded to the second bonding pads 177 of the second redistribution structure 170 by the connection members 181 such that the first semiconductor die 180 and the second redistribution structure 170 are electrically coupled. One or more second semiconductor dies 190 are bonded to the second bonding pads 177 of the second redistribution structure 170 by the connection members 191 such that the second semiconductor dies 190 and the second redistribution structure 170 are electrically coupled.

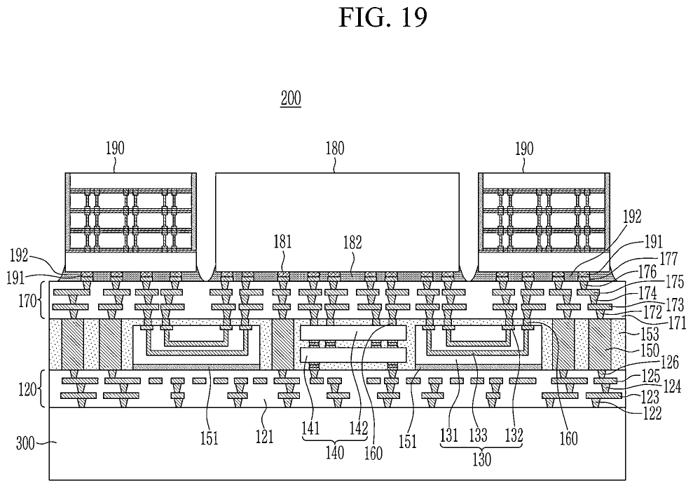

FIG. 19 is a cross-sectional view illustrating an operation of forming the insulating member 182 between the second redistribution structure 170 and the first semiconductor die 180 and forming one or more insulating members 192 between the second redistribution structure 170 and one or more second semiconductor dies 190.

Referring to FIG. 19, the insulating member 182 is formed between the second redistribution structure 170 and the first semiconductor die 180, and one or more insulating members 192 are formed between the second redistribution structure 170 and one or more second semiconductor dies 190. Therefore, it is possible to relieve stress between the second redistribution structure 170 and the first semiconductor die 180 and between the second redistribution structure 170 and one or more second semiconductor dies 190. The insulating member 182 surrounds the second bonding pads 177 and the connection members 181. One or more insulating members 192 surround the second bonding pads 177 and the connection members 191.

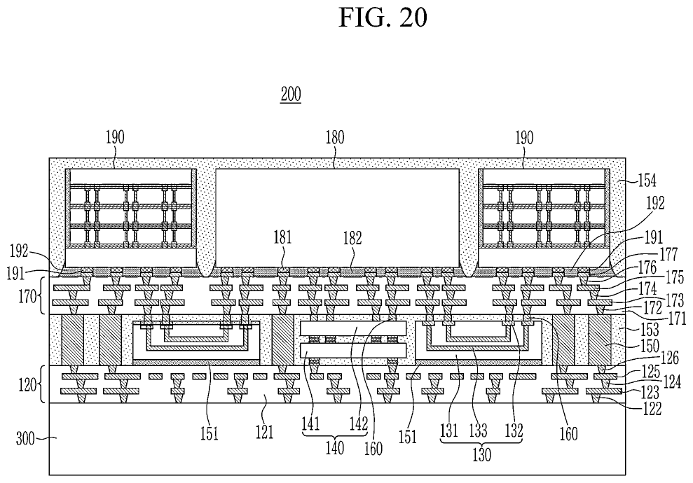

FIG. 20 is a cross-sectional view illustrating an operation of encapsulating the first semiconductor die 180 and one or more second semiconductor dies 190 on the second redistribution structure 170.

Referring to FIG. 20, the first semiconductor die 180 and one or more second semiconductor dies 190 are covered on the second redistribution structure 170 by the second molding material 154. In some example embodiments, the process of performing encapsulating by the second molding material 154 may include a compression molding or transfer molding process. In some example embodiments, the second molding material 154 may comprise an epoxy molding compound (EMC).

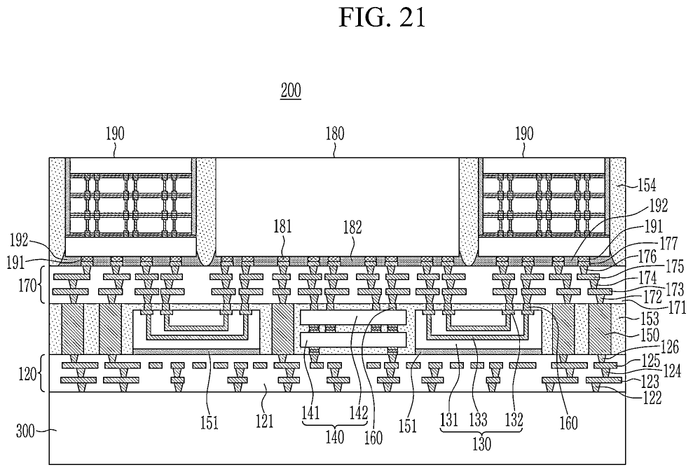

FIG. 21 is a cross-sectional view illustrating an operation of performing a chemical mechanical polishing (CMP) process on the second molding material 154.

Referring to FIG. 21, by performing the chemical mechanical polishing (CMP) process to level the upper surface of the second molding material 154, the upper surface of the second molding material 154 is planarized. After the chemical mechanical polishing (CMP) process is performed, the upper surface of the first semiconductor die 180 and the upper surfaces of one or more second semiconductor dies 190 are exposed.

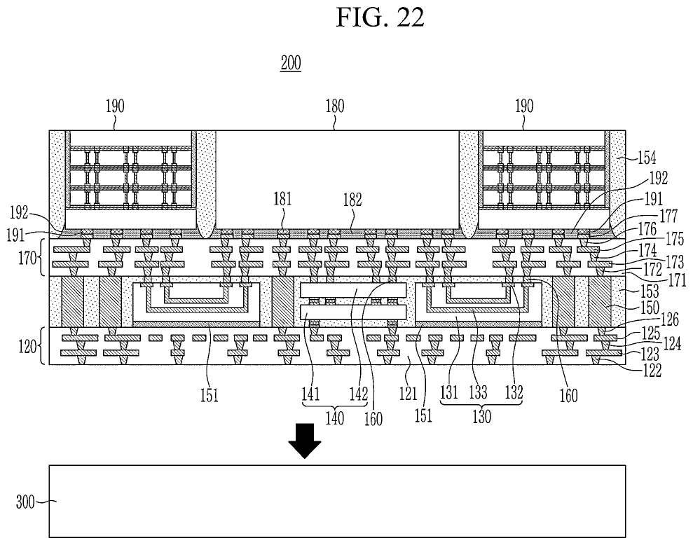

FIG. 22 is a cross-sectional view illustrating an operation of removing the carrier 300 from the first redistribution structure 120.

Referring to FIG. 22, the carrier 300 is removed from the lower surface of the first redistribution structure 120.

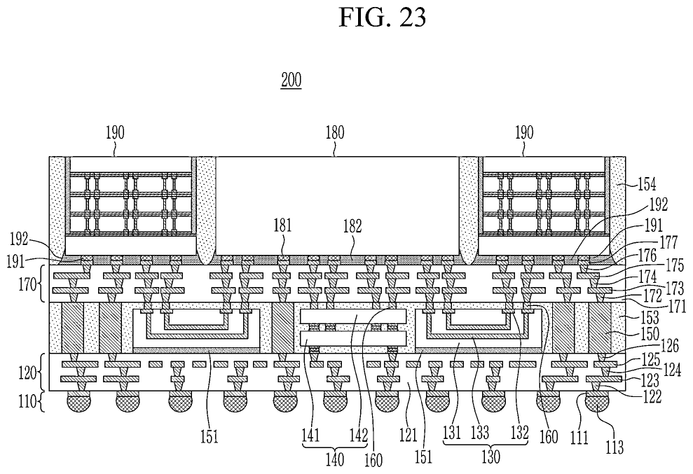

FIG. 23 is a cross-sectional view illustrating an operation of forming the external connection structure 110 on the lower surface of the first redistribution structure 120.

Referring to FIG. 23, the external connection structure 110 is formed on the lower surface of the first redistribution structure 120. The conductive pads 111 are formed below the first redistribution vias 122 of the first redistribution structure 120, and the external connection members 113 are formed below the conductive pads 111. In some example embodiments, the conductive pads 111 may be formed by a sputtering process, or by forming seed metal layers and then performing an electroplating process.

Thereafter, as shown in FIG. 3, the interposer 100 with the first semiconductor die 180 and one or more second semiconductor dies 190 is mounted on the printed circuit board 210 by performing flip chip bonding.

While the inventive concepts have been described in connection with what is presently considered to be practical example embodiments, it is to be understood that the inventive concepts are not limited to the disclosed example embodiments. On the contrary, it is intended to cover various modifications and equivalent arrangements included within the spirit and scope of the appended claims.

What is claimed is:

1. An interposer comprising:
a first redistribution structure;
a device stack structure on the first redistribution structure, the device stack structure including a first device die and a second device die on the first device die, and each of the first device die and the second device die including one or more integrated stack capacitor (ISC) structures;
a plurality of first connection members on the first redistribution structure;
a molding material on the first redistribution structure, the molding material covering the device stack structure and the plurality of first connection members; and
a second redistribution structure on the molding material.

2. The interposer of claim 1, wherein
the device stack structure further includes a third device die on the second device die, and
the third device die includes one or more integrated stack capacitor (ISC) structures.

3. The interposer of claim 1, wherein
each of the first device die and the second device die has a vertical thickness of 30 μm to 50 μm.

4. The interposer of claim 1, further comprising:
a plurality of second connection members between the device stack structure and the second redistribution structure.

5. The interposer of claim 4, wherein
the plurality of second connection members includes micro bumps.

6. The interposer of claim 1, wherein each of the first device die and the second device die include:
a substrate;
an inter-metal dielectric on the substrate;
the one or more integrated stack capacitor (ISC) structures in the inter-metal dielectric;
wiring lines in the inter-metal dielectric; and
contact plugs in the inter-metal dielectric.

7. The interposer of claim 6, wherein
each of the first device die and the second device die further include a plurality of through-silicon vias extending from the inter-metal dielectric and passing through the substrate.

8. The interposer of claim 1, wherein
the molding material comprises an epoxy molding compound (EMC).

9. The interposer of claim 1, wherein
the plurality of first connection members comprises conductive posts.

10. A semiconductor package comprising:
a printed circuit board;
a first redistribution structure on the printed circuit board;
a device stack structure on the first redistribution structure, the device stack structure including a first device die and a second device die on the first device die, and each of the first device die and the second device die including one or more integrated stack capacitor (ISC) structures;
a plurality of connection members on the first redistribution structure;
a molding material on the first redistribution structure, the molding material covering the device stack structure and the plurality of connection members;
a second redistribution structure on the molding material;
a first semiconductor die on the second redistribution structure; and
a second semiconductor die on the second redistribution structure, the second semiconductor die being next to the first semiconductor die.

11. The semiconductor package of claim 10, further comprising:
one or more bridge dies on the first redistribution structure.

12. The semiconductor package of claim 11, wherein
the one or more bridge dies are configured to couple the first semiconductor die and the second semiconductor die.

13. The semiconductor package of claim 10, wherein
the first semiconductor die includes a logic die.

14. The semiconductor package of claim 10, wherein:
the second semiconductor die includes a high bandwidth memory (HBM).

15. A method of manufacturing an interposer, the method comprising:
forming a first redistribution structure on a carrier;
forming a plurality of connection members on the first redistribution structure;
forming a device stack structure on the first redistribution structure, the device stack structure including a first device die and a second device die on the first device die, and each of the first device die and the second device die including one or more integrated stack capacitor (ISC) structures;
covering the plurality of connection members and the device stack structure on the first redistribution structure with a molding material;
planarizing the molding material and the plurality of connection members; and
forming a second redistribution structure on the molding material.

16. The method of manufacturing the interposer according to claim 15, wherein
the forming the device stack structure on the first redistribution structure includes:
mounting the first device die on the first redistribution structure; and
stacking the second device die on the first device die.

17. The method of manufacturing the interposer according to claim 16, wherein
the mounting the first device die on the first distribution structure mounts the first device die on the first redistribution structure with a die attach film (DAF).

18. The method of manufacturing the interposer according to claim 16, wherein
the mounting the first device die on the first redistribution structure comprises attaching the first device die to the first redistribution structure by thermal compression.

19. The method of manufacturing the interposer according to claim 16, wherein
the mounting the first device die on the first redistribution structure comprises attaching the first device die to the first redistribution structure by a flip-chip bonding process.

20. The method of manufacturing the interposer according to claim 15, wherein
the planarizing the molding material and the plurality of connection members is performed by grinding.
